(19) United States
(12) Patent Application Publication
(10) Pub. No.: US 2012/0244459 A1
(43) Pub. Date: Sep. 27, 2012

(54) METHOD FOR EVALUATING OVERLAY ERROR AND MASK FOR THE SAME

(75) Inventors: Kuan Ting CHOU, Taipei City (TW); Pei Cheng FAN, Taoyuan City (TW)

(73) Assignee: NANYA TECHNOLOGY CORP., KUEISHAN (TW)

(21) Appl. No.: 13/071,248

(22) Filed: Mar. 24, 2011

(51) Int. Cl. G03F 1/00; G03F 9/00

(52) U.S. Cl. 430/5; 430/22

(57) ABSTRACT

A mask for evaluating overlay error comprises a plurality of replicate device regions and an overlay mark. The plurality of replicate device regions are disposed uniformly on the mask, wherein each comprises a plurality of device patterns; and a plurality of current layer check patterns are formed adjacent to the plurality of device patterns. The overlay mark is formed on the corner of the mask's peripheral region. In particular, the current layer check patterns are configured to evaluate the pattern offset of a current mask, and the overlay mark and the current layer check patterns are configured to evaluate the overlay error by performing an exposure process using the current mask and a next mask.

### TECHNICAL FIELD

The present invention relates to a method for evaluating overlay error and a mask for the same.

### BACKGROUND

Semiconductor devices are typically constructed with multiple layers, each of which is selectively deposited and etched to fabricate the devices. Because semiconductor devices have decreased in size and increased in density in recent years, photolithography is one of the most critical steps during the manufacturing process. A lithography process generally includes cleaning the surface of a wafer, coating the surface of the wafer with a photoresist material, aligning the wafer with a mask or reticle, exposing the layer of photoresist to light directed by the mask or reticle, and developing the exposed layer of photoresist. The above alignment and exposure steps are executed by an exposure apparatus.

FIG. 1 is a perspective view illustrating a conventional exposure apparatus 10. The conventional exposure apparatus 10 is provided with a wafer 12 on a wafer stage 14 which is movable in the X- or Y-direction. A projection lens 16 is provided above the wafer 12, and a mask 18 with patterns of geometric shapes is placed above the projection lens 16. The mask 18 has a device pattern 182 thereon, and has an overlay mark 184 positioned on the edge of the mask 18. Using the exposure apparatus of the above described structure, the device pattern 182 and the overlay mark 184 on the mask 18 are transferred to the surface of the wafer 14. Referring to FIG. 1, a shot area 19 having exposure patterns 192 and 194 corresponding to the device pattern 182 and overlay mark 184 on the mask 18 are formed on the wafer 12 by an exposure, and a plurality of shots 19 are formed on the wafer 12 by repeating the exposure.

The semiconductor devices are formed by superimposing a plurality of device patterns on the wafer one over another. Because the semiconductor manufacturing process typically involves more than ten masks of different patterns, it is important to align the successive patterned layers so as to reduce the misalignment errors. For alignment purposes, overlay mark patterns having a box-in-box shape are generally used. Referring to FIG. 2, an overlay mark 20 according to the prior art is provided on the mask. The overlay mark 20 has a first rectangular region 22, a second rectangular region 24, a third rectangular region 26 and a fourth rectangular region 28.

Referring to FIG. 2, the longer side of the first rectangular region 22 and the longer side of the third rectangular region 26 are parallel to each other, while the longer side of the second rectangular region 24 and the longer side of the fourth rectangular region 28 are parallel to each other. The longer side of the first rectangular region 22 or the third rectangular region 26 is perpendicular to the longer side of the second rectangular region 24 or the fourth rectangular region 24.

FIG. 3 illustrates a mark pattern 30 previously formed on the wafer after the completion of the lithographic process. The mark pattern 30 includes a first aligned rectangular region 32, a second aligned rectangular region 34, a third aligned rectangular region 36 and a fourth aligned rectangular region 38.

FIG. 4 shows a top view of the wafer having an alignment configuration 40, wherein the pattern shown in FIG. 2 is transferred on the photoresist to form a first rectangular region 42, a second rectangular region 44, a third rectangular region 46 and a fourth rectangular region 48. By measuring variations between the first aligned rectangular region 32, the second aligned rectangular region 34, the third aligned rectangular region 36 and the fourth aligned rectangular region 38 and the first rectangular region 32, the second rectangular region 34, the third rectangular region 36 and the fourth rectangular region 38 respectively, the alignment accuracy can be determined.

However, the prior art overlay mark is only formed on the area around the mask's peripheral region, and the number of overlay marks on the mask is limited. Due to continuing demand for further reduction in scaling of the semiconductor process, greater accuracy of alignment of a plurality of masks becomes more and more important. Therefore, there is a need to provide a simple and cost-effective alignment method to achieve an enhancement in the alignment accuracy.

### SUMMARY

An aspect of the present invention is to provide a method for evaluating overlay error and a mask for the same.

According to one embodiment of the present invention, a method for evaluating overlay error comprises the steps of preparing a first mask comprising a plurality of first replicate device regions and a first overlay mark, wherein the first replicate device regions are disposed uniformly on the mask and the first overlay mark is formed on the corner of the mask's peripheral region, and each device region comprises a plurality of first device patterns and a plurality of first current layer check patterns thereon; preparing a second mask comprising a plurality of second replicate device regions and a second overlay mark, wherein the second replicate device regions are disposed uniformly on the mask and the second overlay mark is formed on the corner of the mask's peripheral region, and each device region comprises a plurality of second device patterns and a plurality of second current layer check patterns thereon; forming a first exposure pattern on a wafer by performing a first exposure process according to the first current layer check patterns on the first mask; forming a second exposure pattern on the wafer by performing a second exposure process according to the second current layer check patterns on the second mask; and measuring deviations between the first and second exposure patterns on the wafer to obtain the overlay error.

In addition, the first and second current layer check patterns are configured to evaluate the pattern offset of the first and second masks, respectively, and the first and second overlay marks and the first and second current layer check patterns are configured to evaluate the overlay error.

According to another embodiment of the present invention, the mask for evaluating overlay error comprises a plurality of replicate device regions and an overlay mark. The plurality of replicate device regions are disposed uniformly on the mask, wherein each comprises a plurality of device patterns; and a plurality of current layer check patterns are formed adjacent to the plurality of device patterns. The overlay mark is formed on the corner of the mask's peripheral region. In particular, the current layer check patterns are configured to evaluate the pattern offset of a current mask, and the overlay mark and the current layer check patterns are configured to evaluate the overlay error by performing an exposure process using the current mask and a next mask.

The foregoing has outlined rather broadly the features and technical advantages of the present invention in order that the detailed description of the invention that follows may be better understood. Additional features and advantages of the invention will be described hereinafter, and form the subject of the claims of the invention. It should be appreciated by those skilled in the art that the conception and specific embodiment disclosed may be readily utilized as a basis for modifying or designing other structures or processes for carrying out the same purposes as those of the present invention. It should also be realized by those skilled in the art that such equivalent constructions do not depart from the spirit and scope of the invention as set forth in the appended claims.

### BRIEF DESCRIPTION OF THE DRAWINGS

The accompanying drawings, which are incorporated in and constitute a part of this specification, illustrate embodiments of the disclosure and, together with the description, serve to explain the principles of the invention.

FIG. 1 is a perspective view illustrating a conventional exposure apparatus;

FIG. 2 illustrates a box-in-box mark pattern formed on a mask as in prior technique;

FIG. 3 illustrates a box-in-box mark pattern formed on a wafer;

FIG. 4 shows a top view of the wafer having an alignment configuration;

FIG. 5 is a mask manufactured in accordance with the present invention;

FIG. 6 is an enlarged view of the device regions on the mask in accordance with the present invention;

FIG. 7 shows a flow chart of a method for evaluating overlay error between a plurality of masks in accordance with one embodiment of the present invention;

FIG. 8 is a mask manufactured in accordance with the present invention;

FIG. 9 is a mask manufactured in accordance with the present invention; and

FIG. 10 is an enlarged view of the first and second exposure patterns after the exposure process;

FIG. 11 shows a mask sequence in accordance with one embodiment of the present invention; and

FIG. 12 is an enlarged view showing a part of multiple exposure patterns after the exposure process.

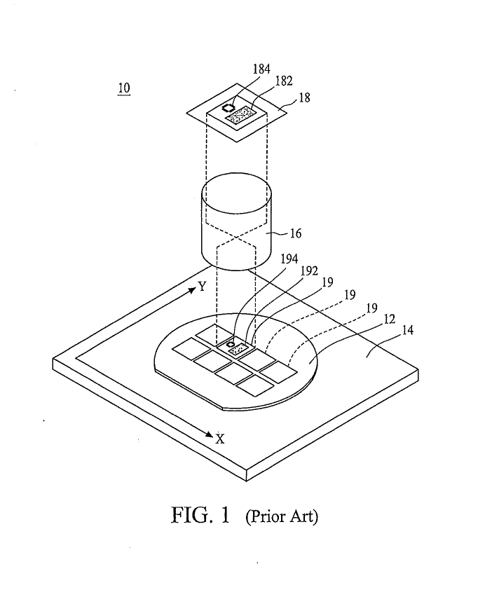

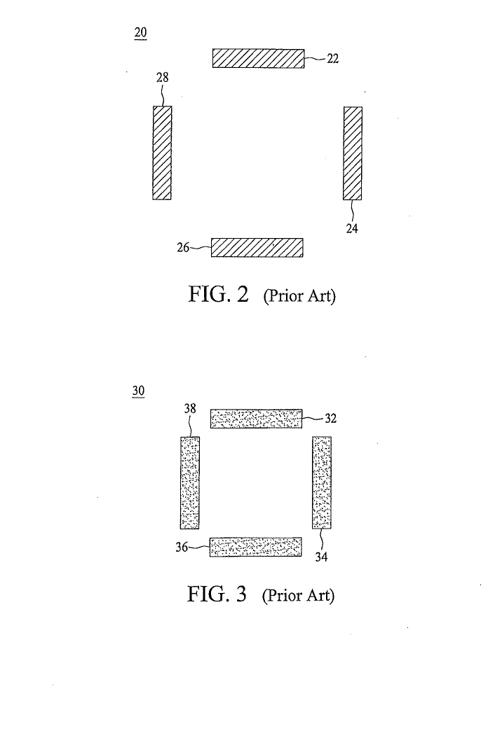

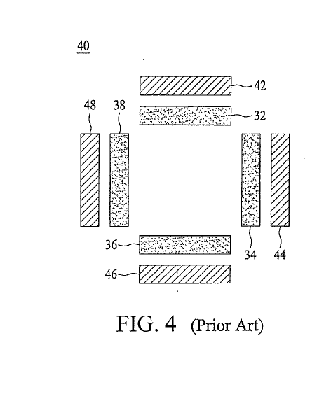

### DETAILED DESCRIPTION

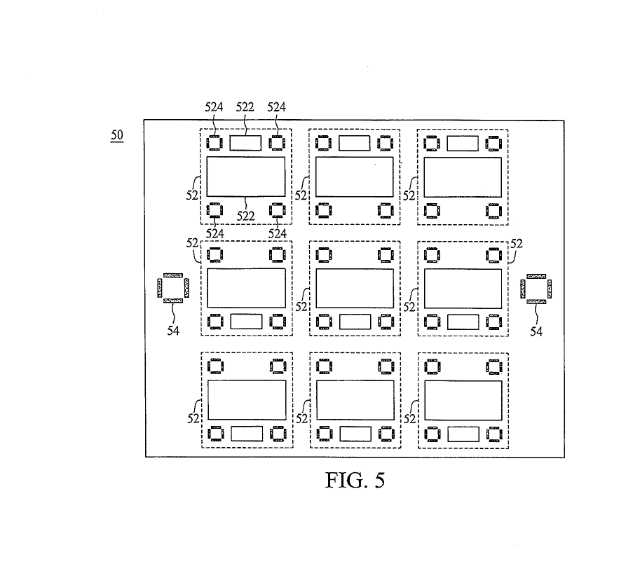

FIG. 5 is a mask 50 manufactured in accordance with one embodiment of the present invention. Referring to FIG. 5, a plurality of replicate device regions 52 are disposed uniformly on the mask 50 and two overlay marks 54 are formed on the peripheral region of the mask 50. Each device region 52 comprises a plurality of device patterns 522 and a plurality of current layer check patterns 524 thereon.

The overlay marks 54 are used for the overlaying alignment between successive masks. According to one embodiment of the present invention, the overlay marks 34 are box-in-box marks or advanced imaging metrology marks for alignment purposes. When the overlay marks 54 are in the form of box-in-box marks, the outer frame (or “box”) consists of four rectangular regions arranged along four sides of a square, and the inner frame (or “box”) also consists of four rectangular regions arranged along four side of a square. The outer frame and the inner frame are concentric if there are no overlay errors between two successive masks. According to one embodiment of the present invention, the overlay marks 54 are in the form of advanced imaging metrology marks which are designed using optical metrology. The advanced imaging metrology marks comprise a periodic structure, and thus are denser than box-in-box marks for reducing possible inaccuracies during the manufacturing process.

The current layer check patterns 524 are configured to check the image offset of the current mask. The mask manufacturing process is briefly described as follows. After designing an integrated circuit, a data file of mask design data is provided to the mask manufacturing facility.

Subsequently, optical proximity correction (OPC) is performed on the graphic data, which may include adding serifs at four corners of a contact hole pattern or adding a hammerhead at an end of a conductive line pattern. In the next step, a process rule check is performed on the graphic data with OPC. The process rule check generally includes a lithography rule check (LRC) and a design rule check (DRC). Subsequently, a repair procedure is performed on the patterns failing to pass the process rule check so that each pattern can pass the process rule check.

Thereafter, the patterns of the mask are formed according to the corrected and repaired graphic data that have been subjected to the OPC and the repair procedure, and the following steps are sequentially performed. A photoresist layer is formed on an opaque layer on a glass substrate, and then an electron beam is used to form patterns in the photoresist layer under the control of a computer that is installed with the corrected and repaired graphic data. Subsequently, development, etching, photoresist removal and cleaning are sequentially performed to finish the fabrication of the mask.

During the above fabrication process of the mask, the size, shapes, and the position of the patterns on the mask may be warped, distorted, or shifted relative to the original graphic data of the mask. In addition, a scaling error of exposure pattern may result from operation or tool error during the photolithography process. Therefore, the current layer check patterns on the mask are required to check the amount of offset of the position of the patterns formed on the mask from the graphic data, and to check the position of the projected image on the wafer from the graphic data.

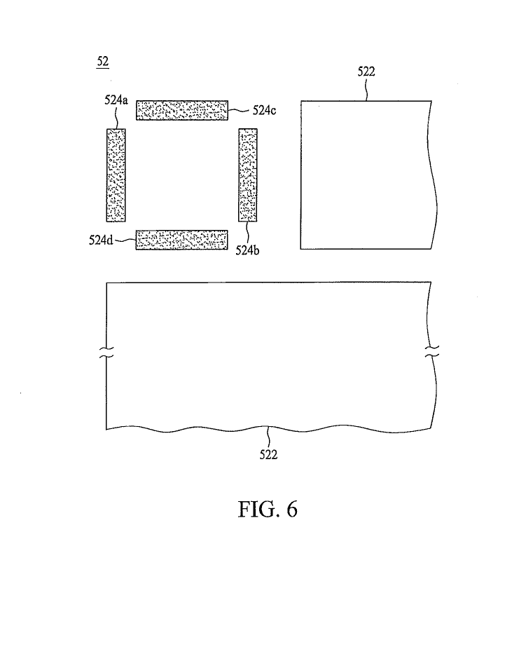

FIG. 6 is an enlarged view of the device regions 52 on the mask 50 in accordance with the present invention. Referring to FIG. 6, the device region 52 has a plurality of device patterns 522 and a plurality of current layer check patterns 524, wherein the device patterns 522 are used to construct semiconductor devices. In one embodiment of the present invention, the current layer check patterns 524 may include at least one rectangular region. Referring to FIG. 6, the current layer check patterns 524 may include a first vertical portion 524a, a second vertical portion 524b, a first horizontal portion 524c, and a second horizontal portion 524d. The vertical portions 524a, 524b may include a series of equally spaced vertical lines, and the horizontal portions 524c, 524d may include a series of equally spaced horizontal lines. The vertical portions 524a, 524b and vertical portions 524a, 524b of the current layer check patterns 524 are arranged along four sides of a square.

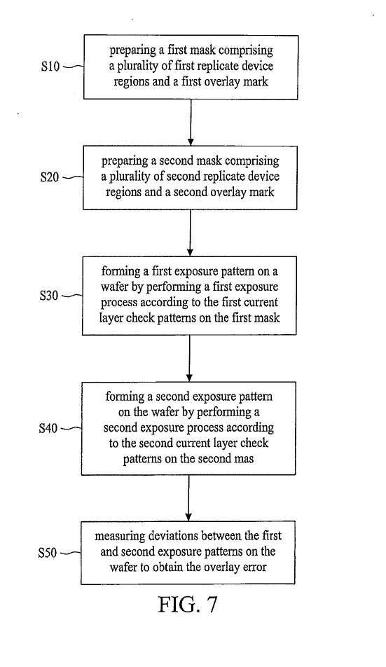

FIG. 7 shows a flow chart of a method for evaluating overlay error in accordance with one embodiment of the present invention. The method comprises preparing a first mask comprising a plurality of first replicate device regions and a first overlay mark in step S10, wherein the first replicate device regions are disposed uniformly on the mask and the first overlay mark is formed on the corner of the mask's peripheral region, and each device region comprises a plurality of first device patterns and a plurality of first current layer check patterns thereon, and preparing a second mask comprising a plurality of second replicate device regions and a second overlay mark in step 20, wherein the second replicate device regions are disposed uniformly on the mask and the second overlay mark is formed on the corner of the mask's peripheral region, and each device region comprises a plurality of second device patterns and a plurality of second current layer check patterns thereon.

The method further comprises forming a first exposure pattern on a wafer by performing a first exposure process according to the first current layer check patterns on the first mask in step S30, forming a second exposure pattern on the wafer by performing a second exposure process according to the second current layer check patterns on the second mask in step S40, and measuring deviations between the first and second exposure patterns on the wafer to obtain the overlay error in step S50.

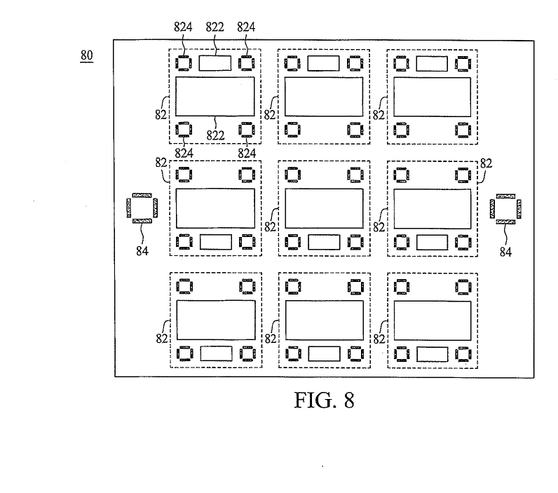

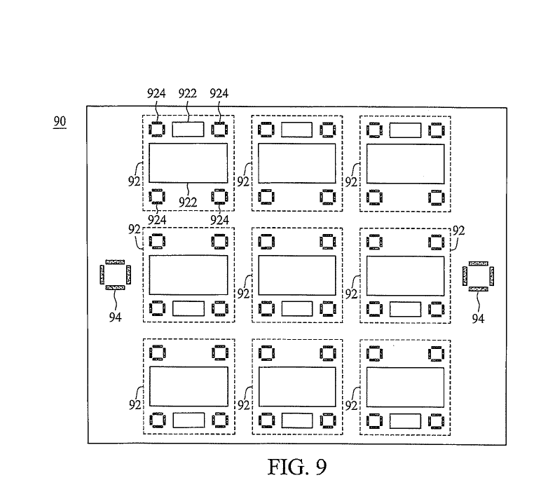

In addition, the first and second current layer check patterns are configured to evaluate the pattern offset of the first and second masks, respectively, and the first and second overlay marks and the first and second current layer check patterns are configured to evaluate the overlay error. The details of the method of the present invention are described in accordance with FIGS. 8 to 10.

Referring to FIG. 8, a first mask 80, similar to the mask 50 shown in FIG. 5, is provided in step S10. The first mask 80 comprises a plurality of replicate device regions 82 formed uniformly on the mask 80 and comprises overlay marks 84 formed on the corner of the mask 80. Each device region 82 comprises a plurality of device patterns 822 and a plurality of current layer check patterns 824.

Referring to FIG. 9, the second mask 90, similar to the mask 50 shown in FIG. 5, is provided in step S20. The second mask 90 comprises a plurality of replicate device regions 92 formed uniformly on the mask 90 and comprises overlay marks 94 formed on the corner of the mask 90. Similarly, each device region 92 has a plurality of device patterns 922 and a plurality of current layer check patterns 924.

Subsequently, a first exposure pattern on a wafer is formed by performing a first exposure process according to the first current layer check patterns 824 on the first mask 80, and a second exposure pattern on the wafer is formed by performing a second exposure process according to the second current layer check patterns 924 on the second mask 90. According to the above steps, the patterns on the first and second mask 80 and 90 are transferred on photoresist coating on the wafer so as to form the first and second exposure patterns.

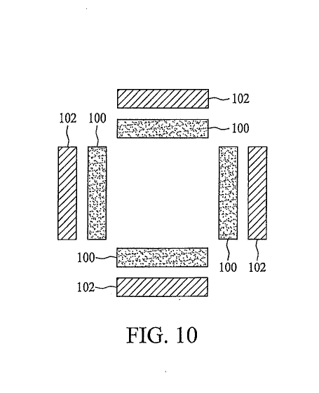

FIG. 10 is an enlarged view showing a part of the first and second exposure patterns 100 and 102 after the exposure process. The deviations between the first and second exposure patterns 100 and 102 on the wafer can be measured to evaluate the overlay error. For example, the offset between the first and second exposure patterns 100 and 102 on the wafer along X-, Y-, or X and Y axes is measured to obtain the offset data. In particular, the present invention measures the deviations between the first and second exposure patterns 100 and 102 based on the corresponding current layer check patterns 824 and 924. Because each device region comprises at least one current layer check pattern and the devices regions are formed uniformly on each mask, many samples of the measured data from different positions of the wafer can be obtained in this manner. In this embodiment, data of thirty-six points from the multiple device regions is obtained. However, since the overlay marks are formed on the peripheral region of the mask, data of two points is merely obtained from the overlay marks. Therefore, the non-ideal factors causing the distortion of the patterns, such as the overlay offset between different masks or the scaling error during the exposure, can be obtained with more data measured according to the method of the present invention.

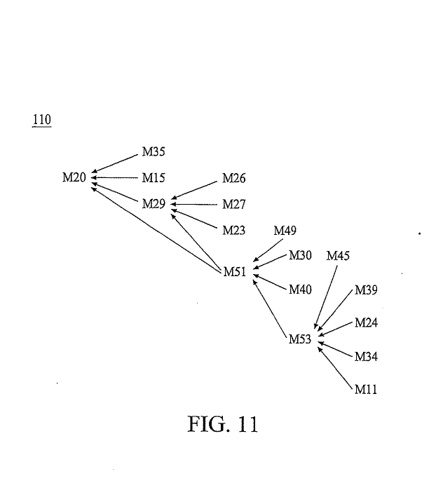

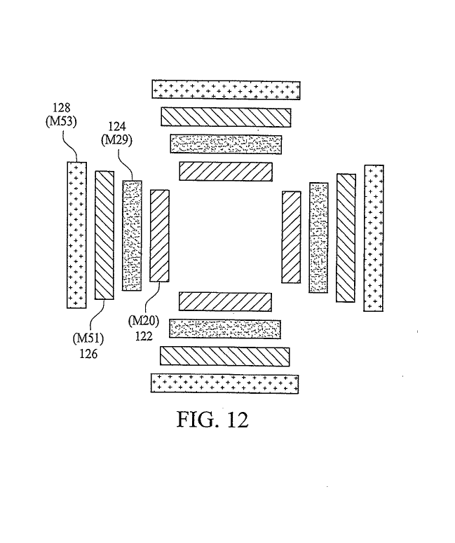

It should be noted that the present invention is applicable to series of masks for photolithography to check the overlay error among a plurality of masks. Therefore, the first and second masks 80 and 90 in FIGS. 8 and 9 can be two continuous or two discontinuous masks. Because semiconductor devices are typically constructed with multiple layers, each of which must be performed in its proper sequence and with good process control in order to produce high-yield semiconductor devices. FIG. 11 shows a mask sequence 110 in accordance with one embodiment of the present invention and semiconductor devices are formed based on the mask sequence 110. The number shown in FIG. 11 represents a mask sequence number, and the relationship between the masks can be found according to the mask sequence 110. For example, masks M26, M27, and M23 have relations with mask M29, and masks M35, M15, and M29 have relations with mask M20. As shown in FIG. 11, masks M20, M29, M51, and M53 are the critical masks in this embodiment since most layers are in connection with them. Therefore, masks M20, M29, M51, and M53 preferably comprise current layer check pattern. FIG. 12 is an enlarged view showing a part of multiple exposure patterns 122, 124, 126, and 128 after the exposure process, wherein the patterns 122, 124, 126, and 128 are formed based on the masks M20, M29, M51, and M53, respectively. The deviations between the patterns 122, 124, 126, and 128 on the wafer can be measured to evaluate the overlay error among the critical masks.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for evaluating overlay error, comprising the steps of:
preparing a first mask comprising a plurality of first replicate device regions and a first overlay mark, wherein the first replicate device regions are disposed uniformly on the mask and the first overlay mark is formed on the corner of the mask's peripheral region, and each device region comprises a plurality of first device patterns and a plurality of first current layer check patterns thereon;
preparing a second mask comprising a plurality of second replicate to device regions and a second overlay mark, wherein the second replicate device regions are disposed uniformly on the mask and the second overlay mark is formed on the corner of the mask's peripheral region, and each device region comprises a plurality of second device patterns and a plurality of second current layer check patterns thereon;
forming a first exposure pattern on a wafer by performing a first exposure process according to the first current layer check patterns on the first mask;
forming a second exposure pattern on the wafer by performing a second exposure process according to the second current layer check patterns on the second mask; and
measuring deviations between the first and second exposure patterns on the wafer to obtain the overlay error;
wherein the first and second current layer check patterns are configured to evaluate the pattern offset of the first and second masks, respectively, and the first and second overlay marks and the first and second current layer check patterns are configured to evaluate the overlay error.

2. The method of claim 1, wherein the first and second overlay marks are box-in-box marks or advanced imaging metrology marks.

3. The method of claim 1, wherein the first and second masks are continuous masks.

4. The method of claim 1, wherein the first and second masks are discontinuous masks.

5. The method of claim 1, wherein each of the first and second current layer check patterns comprises a rectangular portion.

6. The method of claim 1, wherein each of the first and second current layer check patterns comprises first and second vertical portions and first and second horizontal portions.

7. The method of claim 6, wherein the first and second vertical portions and first and second horizontal portions are arranged along four sides of a square.

8. A mask for evaluating overlay error, comprising:
a plurality of replicate device regions disposed uniformly on the mask, the device region each comprising:
a plurality of device patterns; and
a plurality of current layer check patterns formed adjacent to the plurality of device patterns; and
an overlay mark formed on the corner of the mask's peripheral region;
wherein the current layer check patterns are configured to evaluate the pattern offset of a current mask, and the overlay mark and the current layer check patterns are configured to evaluate the overlay error by performing a exposure process using the current mask and a next mask.

9. The mask of claim 8, wherein the overlay mark is a box-in-box mark or an advanced imaging metrology mark.

10. The mask of claim 8, wherein the current mask and the next mask are continuous masks.

11. The mask of claim 8, wherein the current mask and the next mask are discontinuous masks.

12. The mask of claim 8, wherein each of the current layer check patterns comprises a rectangular portion.

13. The mask of claim 8, wherein each of the current layer check patterns comprises first and second vertical portions and first and second horizontal portions.

14. The mask of claim 13, wherein the first and second vertical portions and first and second horizontal portions are arranged along four sides of a square.
